(19) United States
(12) Patent Application Publication
(10) Pub. No.: US 2026/0082800 A1
(43) Pub. Date: Mar. 19, 2026

(54) MANUFACTURING DEVICE OF DISPLAY DEVICE AND MANUFACTURING METHOD OF DISPLAY DEVICE

(71) Applicant: Magnolia White Corporation, Tokyo (JP)

(72) Inventors: Yuki HAMADA, Tokyo (JP); Takanobu TAKENAKA, Tokyo (JP); Hirofumi MIZUKOSHI, Tokyo (JP); Masaru TAKAYAMA, Tokyo (JP)

(73) Assignee: Magnolia White Corporation, Tokyo (JP)

(21) Appl. No.: 19/291,635

(22) Filed: Aug. 6, 2025

(30) Foreign Application Priority Data
Sep. 19, 2024 (JP) 2024-162207

(51) Int. Cl. H10K 71/16; H10K 59/12; H10K 71/60

(52) U.S. Cl. CPC H10K 71/166; H10K 59/1201; H10K 71/60

(57) ABSTRACT

According to one embodiment, a manufacturing device includes an evaporation chamber including an evaporation source configured to emit a material toward a conveyance path for conveying a processing substrate for a display device, and a measurement portion provided on a downstream side of a conveyance direction of the processing substrate relative to the evaporation chamber. The measurement portion includes a chamber having a transmissive window and connected to the evaporation chamber, and a film thickness measurement device provided outside the chamber, facing the transmissive window and configured to optically measure a thickness of a deposited layer formed of the material deposited on the processing substrate.

### CROSS-REFERENCE TO RELATED APPLICATION

This application is based upon and claims the benefit of priority from Japanese Patent Application No. 2024-162207, filed Sep. 19, 2024, the entire contents of which are incorporated herein by reference.

### FIELD

Embodiments described herein relate generally to a manufacturing device of a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing a display element, the management of the thickness of each layer of an organic layer is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram showing a configuration example of a display element 20.

FIG. 11 is a diagram showing a configuration example of a manufacturing device 100.

FIG. 12 is a diagram showing a configuration example of a measurement portion 110-1.

FIG. 13A is a diagram for explaining a method for measuring the thickness of a deposited layer at a plurality of positions.

FIG. 13B is a diagram for explaining another method for measuring the thickness of a deposited layer at a plurality of positions.

FIG. 14A is a diagram showing a processing substrate SUB carried in an evaporation chamber EV1.

FIG. 14B is a diagram showing the processing substrate SUB carried in the measurement portion 110-1.

FIG. 14C is a diagram showing a process of measuring the thickness of the deposited layer.

FIG. 15 is a diagram showing another configuration example of the measurement portion 110-1.

FIG. 16 is a diagram for explaining the method of calculating the thickness of each layer of a deposited layer by the film thickness measurement device 120 shown in FIG. 15.

FIG. 17 is a diagram showing another configuration example of the measurement portion 110-1.

### DETAILED DESCRIPTION

Embodiments described herein aim to provide a manufacturing device of a display device and a manufacturing method of a display device such that the thicknesses of layers which are successively formed can be measured.

In general, according to one embodiment, a manufacturing device of a display device comprises an evaporation chamber comprising an evaporation source configured to emit a material toward a conveyance path for conveying a processing substrate for the display device, and a measurement portion provided on a downstream side of a conveyance direction of the processing substrate relative to the evaporation chamber. The measurement portion comprises a chamber comprising a transmissive window and connected to the evaporation chamber, and a film thickness measurement device provided outside the chamber, facing the transmissive window and configured to optically measure a thickness of a deposited layer formed of the material deposited on the processing substrate.

According to another embodiment, a manufacturing method of a display device comprises forming a lower electrode above a substrate and forming an inorganic insulating layer comprising an aperture overlapping the lower electrode, preparing a processing substrate in which a partition including a lower portion located on the inorganic insulating layer and an upper portion located on the lower portion and protruding from a side surface of the lower portion is formed, and forming an organic layer on the lower electrode in the aperture. The forming the organic layer includes carrying the processing substrate into an evaporation chamber, depositing a material emitted from an evaporation source on the processing substrate while conveying the processing substrate in the evaporation chamber, carrying the processing substrate carried out of the evaporation chamber into a chamber of a measurement portion, and stopping the processing substrate and optically measuring a thickness of a deposited layer formed of the material deposited on the processing substrate in the measurement portion.

The embodiments can provide a manufacturing device of a display device and a manufacturing method of a display device such that the thicknesses of layers which are successively formed can be measured.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various types of elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

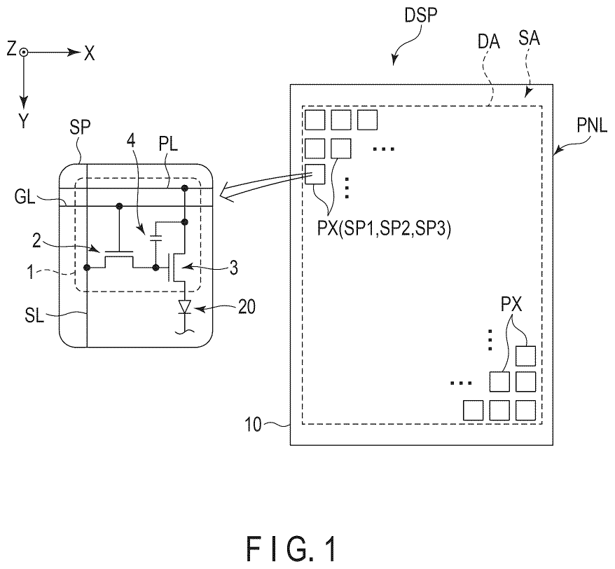

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, a terminal for connecting an IC chip and a flexible printed circuit is provided in the surrounding area SA.

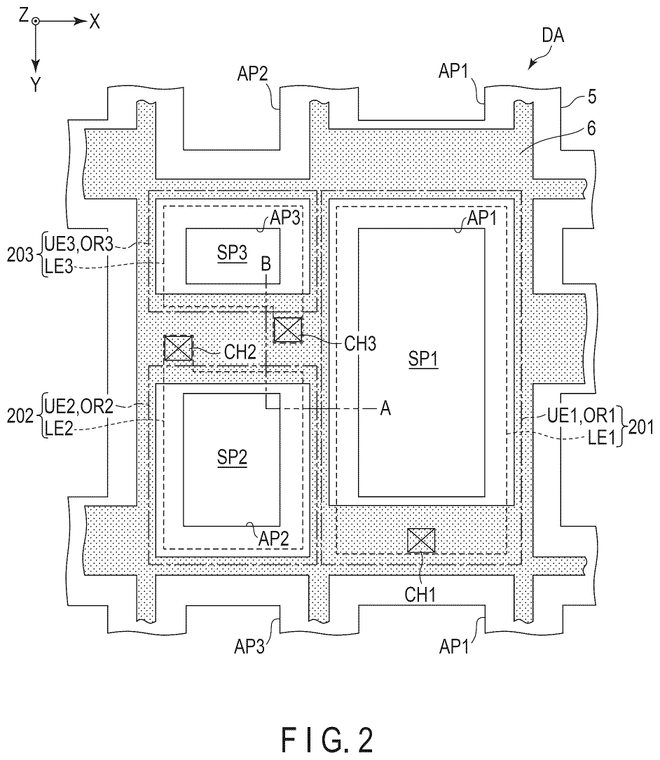

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 comprises apertures AP1, AP2 and AP3 in subpixels SP1, SP2 and SP3, respectively. The inorganic insulating layer 5 comprising these apertures AP1, AP2 and AP3 may be called a rib.

The partition 6 overlaps the inorganic insulating layer 5 as seen in plan view. The partition 6 is formed into a grating shape surrounding the apertures AP1, AP2 and AP3. In other words, the partition 6 comprises apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 as seen in plan view. The peripheral portion of each of the organic layer OR1 and the upper electrode UE1 overlaps the inorganic insulating layer 5 as seen in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 as seen in plan view. The peripheral portion of each of the organic layer OR2 and the upper electrode UE2 overlaps the inorganic insulating layer 5 as seen in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 as seen in plan view. The peripheral portion of each of the organic layer OR3 and the upper electrode UE3 overlaps the inorganic insulating layer 5 5 as seen in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

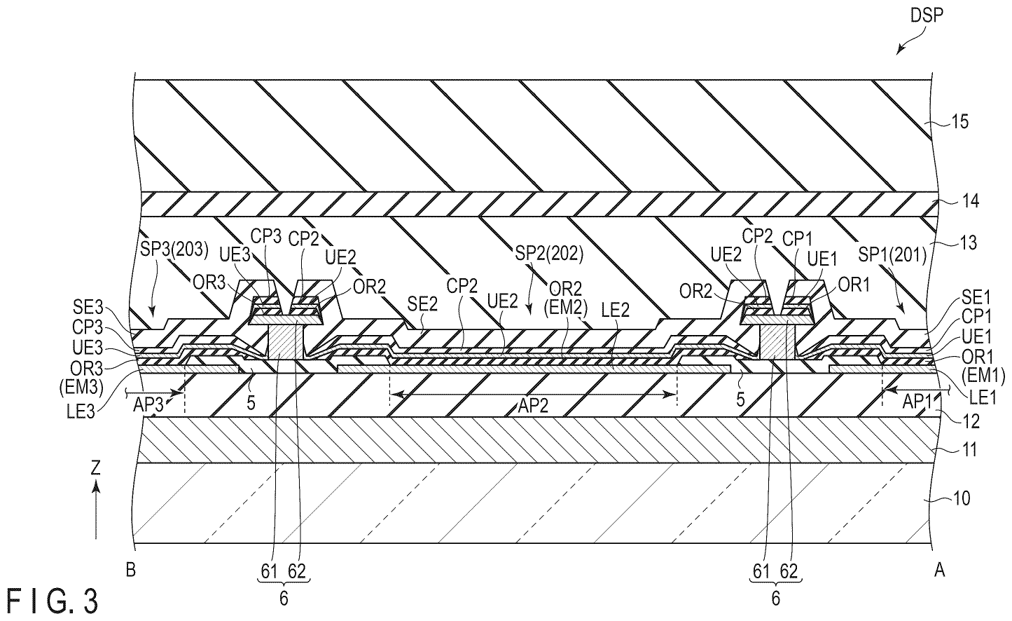

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the inorganic insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

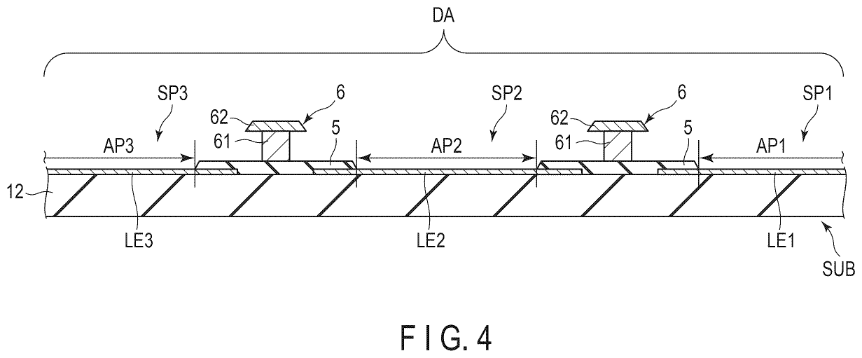

Now, this specification explains the manufacturing method of the display device DSP with reference to FIG. 4 to FIG. 9. In FIG. 4 to FIG. 9, the illustration of the lower side of the insulating layer 12 is omitted.

First, as shown in FIG. 4, a processing substrate SUB is prepared. The process of preparing the processing substrate SUB includes the process of forming the lower electrode LE1 of subpixel SP1, the lower electrode LE2 of subpixel SP2 and the lower electrode LE3 of subpixel SP3 on the insulating layer 12, the process of forming the inorganic insulating layer 5 comprising the apertures AP1, AP2 and AP3 overlapping the lower electrodes LE1, LE2 and LE3, respectively, and the process of forming the partition 6 including the lower portion 61 located on the inorganic insulating layer 5 and the upper portion 62 located on the lower portion 61 and protruding from the side surfaces of the lower portion 61. It should be noted that the partition 6 may be formed after the formation of the inorganic insulating layer 5 comprising the apertures AP1, AP2 and AP3. Alternatively, the apertures AP1, AP2 and AP3 may be formed after the formation of the partition 6.

Subsequently, the display element 201 is formed.

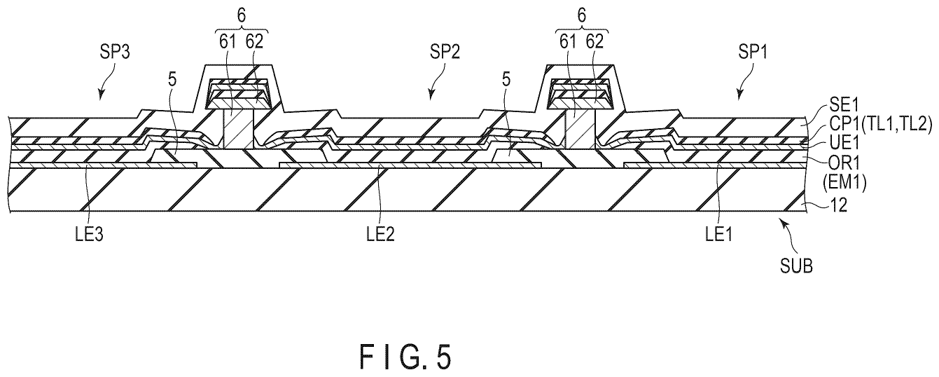

First, the processing substrate SUB is carried in a manufacturing device (in-line evaporation device) 100 as described later. Subsequently, as shown in FIG. 5, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series using the partition 6 as a mask.

Subsequently, the upper electrode UE1 is formed by depositing a mixture of magnesium and silver on the organic layer OR1 using the partition 6 as a mask. The upper electrode UE1 covers the organic layer OR1 and is in contact with the lower portion 61.

Subsequently, the cap layer CP1 is formed by depositing a high-refractive material for forming a first transparent layer TL1 and a low-refractive material for forming a second transparent layer TL2 in series on the upper electrode UE1 using the partition 6 as a mask.

These organic layer OR1, upper electrode UE1 and cap layer CP1 are successively formed while maintaining a vacuum environment.

Subsequently, the processing substrate SUB is carried in a chemical vapor deposition (CVD) device. The sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

The sealing layer SE1 covers the cap layer CP1 located immediately above the partition 6, covers the cap layer CP1 located immediately above the lower electrode LE1 and is in contact with the partition 6.

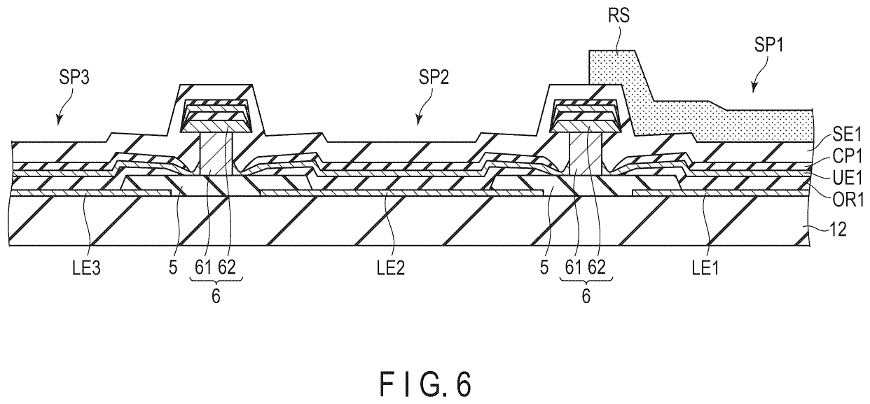

Subsequently, as shown in FIG. 6, a resist RS patterned into a predetermined shape is formed on the sealing layer SE1. The resist RS overlaps subpixel SP1 and part of the partition 6 around subpixel SP1.

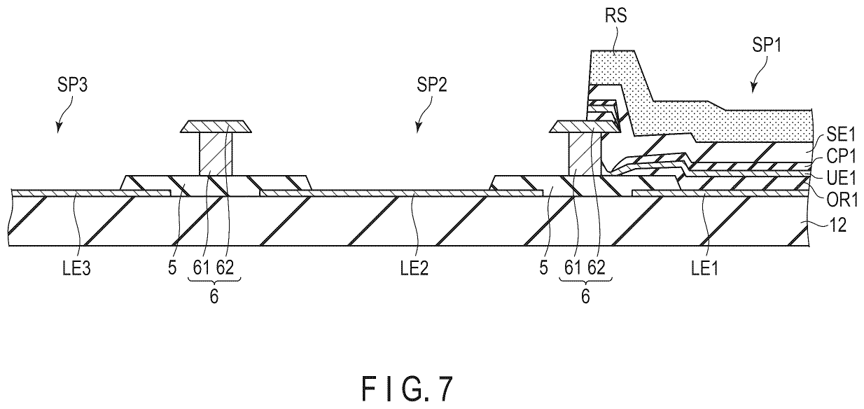

Subsequently, as shown in FIG. 7, the sealing layer SE1, cap layer CP1, upper electrode UE1 and organic layer OR1 exposed from the resist RS are removed in series by performing etching using the resist RS as a mask. In this manner, the lower electrode LE2 of subpixel SP2 and the lower electrode LE3 of subpixel SP3 are exposed.

Subsequently, the resist RS is removed. By this process, the display element 201 is formed in subpixel SP1.

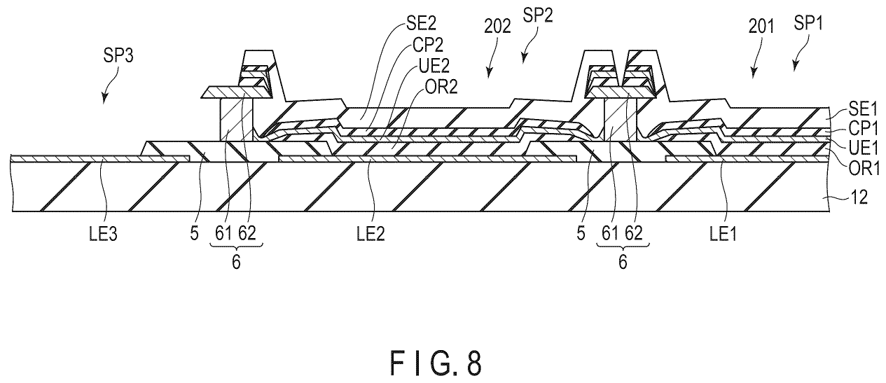

Subsequently, as shown in FIG. 8, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

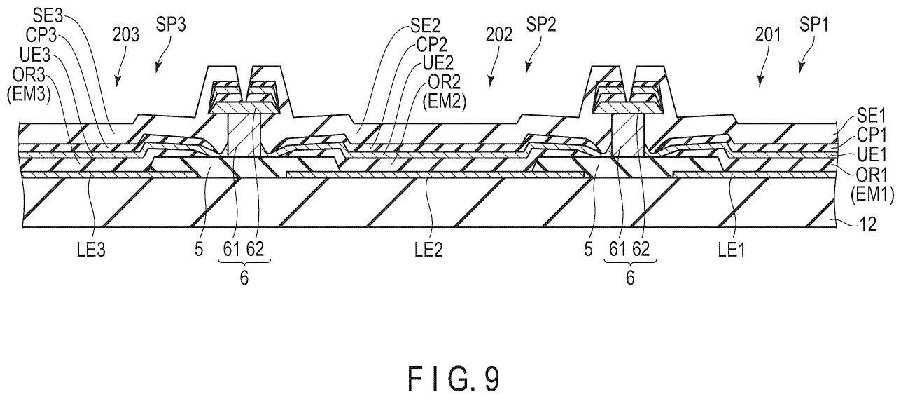

Subsequently, as shown in FIG. 9, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains a configuration example of the display element 20.

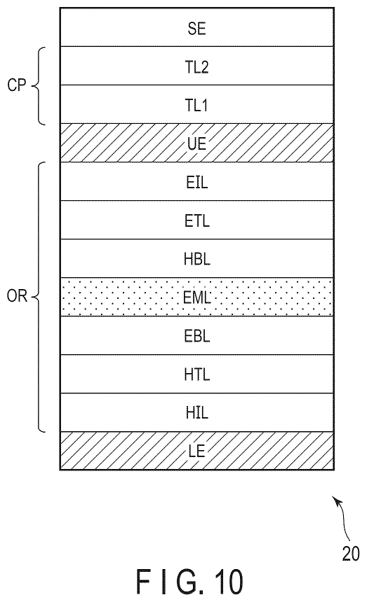

FIG. 10 is a diagram showing a configuration example of a display element 20.

The display element 20 shown in FIG. 10 could correspond to any one of the display elements 201, 202 and 203 described above.

Here, this specification explains an example in which a lower electrode LE corresponds to an anode and an upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL, an electron blocking layer EBL, a light emitting layer EML, a hole blocking layer HBL, an electron transport layer ETL and an electron injection layer EIL are stacked in this order.

It should be noted that the organic layer OR may include, in addition to the functional layers described above, other functional layers such as a carrier generation layer as needed, or at least one of the above functional layers may be omitted.

The light emitting layer EML corresponds to one of the light emitting layers EM1, EM2 and EM3 shown in FIG. 3.

A cap layer CP (CP1, CP2 or CP3) includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2.

It should be noted that the configuration of the organic layer OR is not limited to the configuration in which the organic layer OR comprises the light emitting layer EML consisting of a single layer as shown in the figure. The organic layer OR may comprise a plurality of light emitting layers.

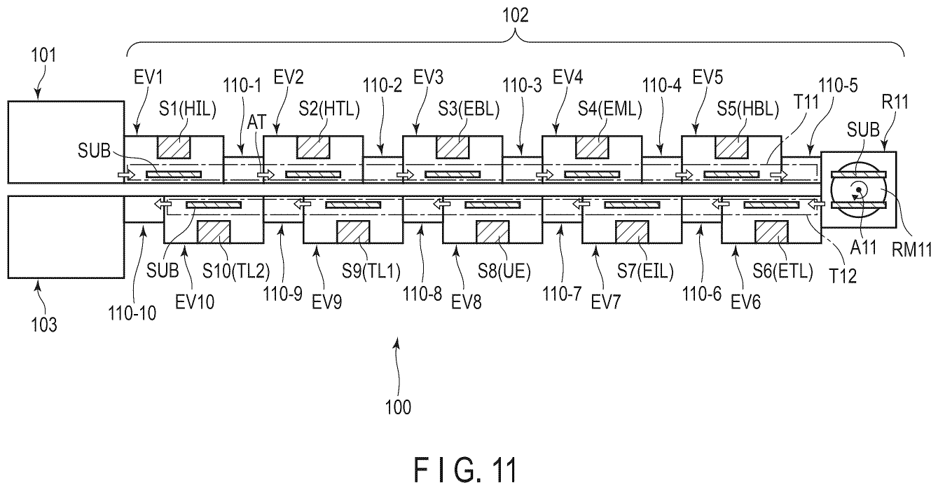

FIG. 11 is a diagram showing a configuration example of the manufacturing device 100.

The manufacturing device 100 is applied in, for example, the process of successively forming the organic layer OR, the upper electrode UE and the cap layer CP. A processing substrate SUB which is supposed to be carried in the manufacturing device 100 comprises the circuit layer 11, the insulating layer 12, the lower electrodes LE1, LE2 and LE3, the inorganic insulating layer 5 and the partition 6 on the substrate 10.

The manufacturing device 100 comprises a preprocessing portion 101, an evaporation portion 102 and a post-processing portion 103.

The preprocessing portion 101 comprises a mechanism which performs various preprocesses for a processing substrate SUB which was carried in, such as a cleaning process, a drying process and a plasma process. The preprocessing portion 101 comprises a mechanism which sets the processing substrate SUB so as to be in a predetermined conveyance posture, a mechanism which secures the processing substrate SUB to a dedicated carrier by an electrostatic chuck, etc. Each conveyance path of the evaporation portion 102 is configured to convey the carrier.

The post-processing portion 103 comprises a mechanism which releases the securing applied by the electrostatic chuck and removes the processing substrate SUB from the carrier, a mechanism which sets the processing substrate SUB so as to be in a predetermined posture, etc.

For example, the posture of the processing substrate SUB carried in the preprocessing portion 101 is a horizontal posture. The posture of the processing substrate SUB is changed from a horizontal posture to a perpendicular posture in the preprocessing portion 101. The posture of the processing substrate SUB carried in the evaporation portion 102 is a perpendicular posture. The posture of the processing substrate SUB is changed from a perpendicular posture to a horizontal posture in the post-processing portion 103.

The evaporation portion 102 comprises a plurality of evaporation chambers EV1 to EV10, a rotation chamber R11 and a plurality of measurement portions 110-1 to 110-10. The preprocessing portion 101, the post-processing portion 103, the evaporation chambers EV1 to EV10, the rotation chamber R11 and the measurement portions 110-1 to 110-10 are connected to each other and are maintained as a high vacuum.

The evaporation chambers EV1 to EV5 are arranged in a line. The evaporation chamber EV1 is connected to the preprocessing portion 101. The measurement portion 110-1 is provided between the evaporation chamber EV1 and the evaporation chamber EV2 and connects them to each other. The measurement portion 110-2 is provided between the evaporation chamber EV2 and the evaporation chamber EV3 and connects them to each other. The measurement portion 110-3 is provided between the evaporation chamber EV3 and the evaporation chamber EV4 and connects them to each other. The measurement portion 110-4 is provided between the evaporation chamber EV4 and the evaporation chamber EV5 and connects them to each other. The measurement portion 110-5 is provided between the evaporation chamber EV5 and the rotation chamber R11 and connects them to each other. A conveyance path T11 is provided over the evaporation chambers EV1 to EV5 and the measurement portions 110-1 to 110-5.

The evaporation chambers EV6 to EV10 are arranged in a line. The evaporation chamber EV6 is connected to the rotation chamber R11. The measurement portion 110-6 is provided between the evaporation chamber EV6 and the evaporation chamber EV7 and connects them to each other. The measurement portion 110-7 is provided between the evaporation chamber EV7 and the evaporation chamber EV8 and connects them to each other. The measurement portion 110-8 is provided between the evaporation chamber EV8 and the evaporation chamber EV9 and connects them to each other. The measurement portion 110-9 is provided between the evaporation chamber EV9 and the evaporation chamber EV10 and connects them to each other. The measurement portion 110-10 is provided between the evaporation chamber EV10 and the post-processing portion 103 and connects them to each other. A conveyance path T12 is provided over the evaporation chambers EV6 to EV10 and the measurement portions 110-6 to 110-10.

Thus, the evaporation portion 102 comprises a set including an evaporation chamber and a measurement portion provided on the downstream side of the conveyance direction of the processing substrate SUB relative to the evaporation chamber. In the evaporation portion 102, a plurality of sets are arranged, and further, the evaporation chambers and the measurement portions are alternately arranged. At least one of the measurement portions 110-1 to 110-10 may be omitted.

The evaporation chamber EV1 comprises an evaporation source S1. The evaporation source S1 is configured to emit a material for forming a hole injection layer HIL toward the conveyance path T11.

The evaporation chamber EV2 comprises an evaporation source S2. The evaporation source S2 is configured to emit a material for forming a hole transport layer HTL toward the conveyance path T11.

The evaporation chamber EV3 comprises an evaporation source S3. The evaporation source S3 is configured to emit a material for forming an electron blocking layer EBL toward the conveyance path T11.

The evaporation chamber EV4 comprises an evaporation source S4. The evaporation source S4 is configured to emit a material for forming a light emitting layer EML toward the conveyance path T11.

The evaporation chamber EV5 comprises an evaporation source S5. The evaporation source S5 is configured to emit a material for forming a hole blocking layer HBL toward the conveyance path T11.

The evaporation chamber EV6 comprises an evaporation source S6. The evaporation source S6 is configured to emit a material for forming an electron transport layer ETL toward the conveyance path T12.

The evaporation chamber EV7 comprises an evaporation source S7. The evaporation source S7 is configured to emit a material for forming an electron injection layer EIL toward the conveyance path T12.

The evaporation chamber EV8 comprises an evaporation source S8. The evaporation source S8 is configured to emit a material for forming an upper electrode UE toward the conveyance path T12.

The evaporation chamber EV9 comprises an evaporation source S9. The evaporation source S9 is configured to emit a material for forming a first transparent layer TL1 toward the conveyance path T12.

The evaporation chamber EV10 comprises an evaporation source S10. The evaporation source S10 is configured to emit a material for forming a second transparent layer TL2 toward the conveyance path T12.

The conveyance path T11 and the conveyance path T12 are provided inside the evaporation portion 102. The evaporation sources S1 to S10 are provided outside the conveyance path T11 and the conveyance path T12 in the evaporation portion 102.

The rotation chamber R11 is configured to convey the processing substrate SUB which is carried out of the conveyance path T11 to the conveyance path T12. The rotation chamber R11 comprises a rotation mechanism RM11. The rotation mechanism RM11 is configured to hold the processing substrate SUB which is carried in the rotation chamber R11 via the conveyance path T11 and rotate around a rotation axis A11.

This specification hereinafter explains the manufacturing process in the manufacturing device 100.

First, a processing substrate SUB in which a lower electrode LE has been formed is carried in the preprocessing portion 101. In the preprocessing portion 101, a predetermined preprocess is performed for the processing substrate SUB.

Subsequently, the processing substrate SUB is carried in the evaporation chamber EV1. In the evaporation chamber EV1, the material emitted from the evaporation source S1 is deposited on the processing substrate SUB conveyed in the conveyance path T11. By this process, a hole injection layer HIL is formed on the lower electrode LE.

The processing substrate SUB carried out of the evaporation chamber EV1 is carried in the measurement portion 110-1. In the measurement portion 110-1, the thickness of the hole injection layer HIL which is the deposited layer formed in the evaporation chamber EV1 is measured.

Subsequently, the processing substrate SUB carried out of the measurement portion 110-1 is carried in the evaporation chamber EV2. In the evaporation chamber EV2, the material emitted from the evaporation source S2 is deposited on the processing substrate SUB conveyed in the conveyance path T11. By this process, a hole transport layer HTL is formed on the hole injection layer HIL.

The processing substrate SUB carried out of the evaporation chamber EV2 is carried in the measurement portion 110-2. In the measurement portion 110-2, the thickness of the hole transport layer HTL which is the deposited layer formed in the evaporation chamber EV2 is measured.

Subsequently, the processing substrate SUB carried out of the measurement portion 110-2 is carried in the evaporation chamber EV3. In the evaporation chamber EV3, the material emitted from the evaporation source S3 is deposited on the processing substrate SUB conveyed in the conveyance path T11. By this process, an electron blocking layer EBL is formed on the hole transport layer HTL.

The processing substrate SUB carried out of the evaporation chamber EV3 is carried in the measurement portion 110-3. In the measurement portion 110-3, the thickness of the electron blocking layer EBL which is the deposited layer formed in the evaporation chamber EV3 is measured.

Subsequently, the processing substrate SUB carried out of the measurement portion 110-3 is carried in the evaporation chamber EV4. In the evaporation chamber EV4, the material emitted from the evaporation source S4 is deposited on the processing substrate SUB conveyed in the conveyance path T11. By this process, a light emitting layer EML is formed on the electron blocking layer EBL.

The processing substrate SUB carried out of the evaporation chamber EV4 is carried in the measurement portion 110-4. In the measurement portion 110-4, the thickness of the light emitting layer EML which is the deposited layer formed in the evaporation chamber EV4 is measured.

Subsequently, the processing substrate SUB carried out of the measurement portion 110-4 is carried in the evaporation chamber EV5. In the evaporation chamber EV5, the material emitted from the evaporation source S5 is deposited on the processing substrate SUB conveyed in the conveyance path T11. By this process, a hole blocking layer HBL is formed on the light emitting layer EML.

The processing substrate SUB carried out of the evaporation chamber EV5 is carried in the measurement portion 110-5. In the measurement portion 110-5, the thickness of the hole blocking layer HBL which is the deposited layer formed in the evaporation chamber EV5 is measured.

Subsequently, the processing substrate SUB carried out of the measurement portion 110-5 is carried in the rotation chamber R11. In the rotation chamber R11, the rotation mechanism RM11 holds the processing substrate SUB which was carried in. The rotation mechanism RM11 rotate 180° while holding the processing substrate SUB.

Subsequently, the processing substrate SUB is carried in the evaporation chamber EV6. In the evaporation chamber EV6, the material emitted from the evaporation source S6 is deposited on the processing substrate SUB conveyed in the conveyance path T12. By this process, an electron transport layer ETL is formed on the hole blocking layer HBL.

The processing substrate SUB carried out of the evaporation chamber EV6 is carried in the measurement portion 110-6. In the measurement portion 110-6, the thickness of the electron transport layer ETL which is the deposited layer formed in the evaporation chamber EV6 is measured.

Subsequently, the processing substrate SUB carried out of the measurement portion 110-6 is carried in the evaporation chamber EV7. In the evaporation chamber EV7, the material emitted from the evaporation source S7 is deposited on the processing substrate SUB conveyed in the conveyance path T12. By this process, an electron injection layer EIL is formed on the electron transport layer ETL.

The processing substrate SUB carried out of the evaporation chamber EV7 is carried in the measurement portion 110-7. In the measurement portion 110-7, the thickness of the electron injection layer EIL which is the deposited layer formed in the evaporation chamber EV7 is measured.

Subsequently, the processing substrate SUB carried out of the measurement portion 110-7 is carried in the evaporation chamber EV8. In the evaporation chamber EV8, the material emitted from the evaporation source S8 is deposited on the processing substrate SUB conveyed in the conveyance path T12. By this process, an upper electrode UE is formed on the electron injection layer EIL.

The processing substrate SUB carried out of the evaporation chamber EV8 is carried in the measurement portion 110-8. In the measurement portion 110-8, the thickness of the upper electrode UE which is the deposited layer formed in the evaporation chamber EV8 is measured.

Subsequently, the processing substrate SUB carried out of the measurement portion 110-8 is carried in the evaporation chamber EV9. In the evaporation chamber EV9, the material emitted from the evaporation source S9 is deposited on the processing substrate SUB conveyed in the conveyance path T12. By this process, a first transparent layer TL1 is formed on the upper electrode UE.

The processing substrate SUB carried out of the evaporation chamber EV9 is carried in the measurement portion 110-9. In the measurement portion 110-9, the thickness of the first transparent layer TL1 which is the deposited layer formed in the evaporation chamber EV9 is measured.

Subsequently, the processing substrate SUB carried out of the measurement portion 110-9 is carried in the evaporation chamber EV10. In the evaporation chamber EV10, the material emitted from the evaporation source S10 is deposited on the processing substrate SUB conveyed in the conveyance path T12. By this process, a second transparent layer TL2 is formed on the first transparent layer TL1.

The processing substrate SUB carried out of the evaporation chamber EV10 is carried in the measurement portion 110-10. In the measurement portion 110-10, the thickness of the second transparent layer TL2 which is the deposited layer formed in the evaporation chamber EV10 is measured.

Subsequently, the processing substrate SUB carried out of the measurement portion 110-10 is carried in the post-processing portion 103. In the post-processing portion 103, a predetermined post-process is performed for the processing substrate SUB.

Subsequently, the processing substrate SUB is carried in a CVD device. In the CVD device, an inorganic insulating material is deposited on the processing substrate SUB. By this process, a sealing layer SE which continuously covers a cap layer CP and a partition 6 is formed.

According to the in-line manufacturing device 100 comprising this configuration, as a measurement portion is adjacent to the downstream side of each evaporation chamber, the thickness of the deposited layer formed in each evaporation chamber can be measured. Moreover, the thickness can be measured in a state where a processing substrate SUB is present inside the evaporation portion 102.

Now, the measurement portions are explained. All of the measurement portions 110-1 to 110-10 shown in FIG. 11 comprise the same configuration. Thus, here, of these measurement portions, the configuration of the measurement portion 110-1 is explained.

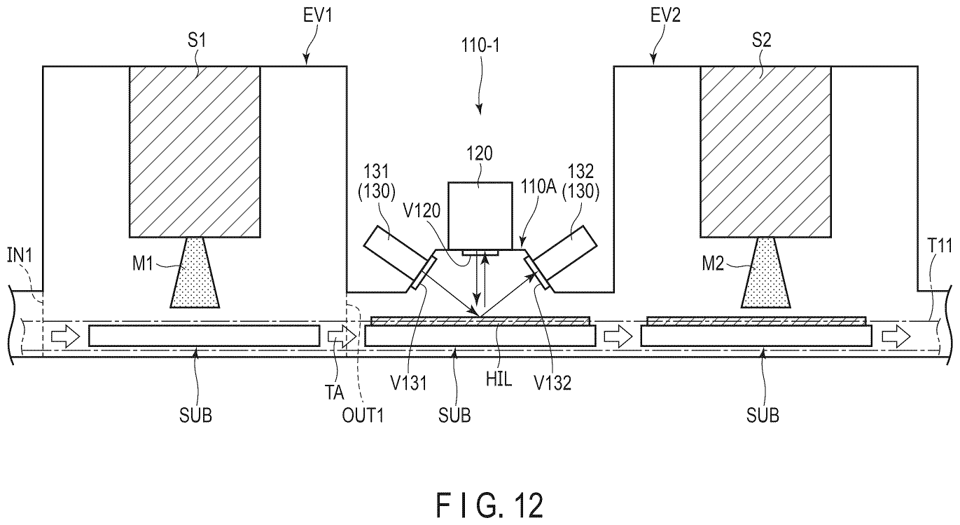

FIG. 12 is a diagram showing a configuration example of the measurement portion 110-1.

The measurement portion 110-1 is provided between the evaporation chamber EV1 and the evaporation chamber EV2. Arrow TA shows the conveyance direction of the processing substrate SUB. The measurement portion 110-1 is provided on the downstream side along the conveyance direction TA relative to the evaporation chamber EV1. The evaporation chamber EV2 is provided on the downstream side along the conveyance direction TA relative to the measurement portion 110-1.

In the evaporation chamber EV1, a material M1 is emitted from the evaporation source S1. In the evaporation chamber EV2, a material M2 is emitted from the evaporation source S2. The processing substrate SUB is conveyed to the evaporation chamber EV1, the measurement portion 110-1 and the evaporation chamber EV in this order. In the evaporation chamber EV1, the material M1 is deposited on the processing substrate SUB, and the deposited layer of the material M1 is formed. In the measurement portion 110-1, the thickness of the deposited layer formed in the evaporation chamber EV1 is measured. In the evaporation chamber EV2, the material M2 is deposited on the processing substrate SUB, and the deposited layer of the material M2 is formed. Each of the evaporation source S1 of the evaporation chamber EV1 and the evaporation source S2 of the evaporation chamber EV2 comprises a plurality of nozzles arranged in a direction intersecting with the conveyance direction TA.

In the example shown in the figure, the deposited layer formed in the evaporation chamber EV1 is a hole injection layer HIL. In the measurement portion 110-1, the thickness of the hole injection layer HIL is measured.

The measurement portion 110-1 comprises a chamber 110A and film thickness measurement devices 120 and 130. In the measurement portion 110-1, the processing substrate SUB is suspended, and the film thickness measurement devices 120 and 130 measure the thickness of the deposited layer during the suspension.

The chamber 110A is connected to the evaporation chamber EV1 and the evaporation chamber EV2. The inside of the chamber 110A is maintained as a high vacuum in a manner similar to that of the evaporation chamber EV1 and the evaporation chamber EV2. The chamber 110A comprises transmissive windows V120, V131 and V132. These transmissive windows V120, V131 and V132 are provided on a side facing the deposited layer formed in the processing substrate SUB (in the example shown in FIG. 12, the hole injection layer HIL).

The film thickness measurement device 120 is a spectroscopic interferometer configured to optically measure the thickness of the deposited layer based on the principle of spectroscopic interferometry. The film thickness measurement device 120 is provided outside the chamber 110A, in other words, in an environment of an atmospheric pressure, and faces the transmissive window V120. Although not described in detail, the film thickness measurement device 120 comprises an emission portion which emits light toward the deposited layer, and a light-receiving portion which receives interfering light in the deposited layer. The film thickness measurement device 120 analyzes the spectrum of the received interfering light and calculates the thickness of the deposited layer based on the wavelength of light and the optical path length. This film thickness measurement device 120 is suitable for the measurement of the total thickness of multilayer films.

The film thickness measurement device 130 is an ellipsometer configured to optically measure the thickness of the deposited layer using a phase modulation method or a rotating-analyzer method. The film thickness measurement device 130 is provided outside the chamber 110A, in other words, in an environment of an atmospheric pressure. The film thickness measurement device 130 comprises an emission portion 131 which emits light toward the deposited layer in an oblique direction which inclines with respect to the normal of the processing substrate SUB, and a light-receiving portion 132 which receives light reflected on the deposited layer. The emission portion 131 faces the transmissive window V131. The light-receiving portion 132 faces the transmissive window V132. The film thickness measurement device 130 calculates the thickness of the deposited layer based on the polarization state of the reflected light received in the light-receiving portion 132. This film thickness measurement device 130 is suitable for the measurement of the thickness of single-layer films.

In this configuration example, the film thickness measurement device 120 and the film thickness measurement device 130 are provided as measurement devices. Thus, the thickness of the deposited layer can be accurately measured using at least one of the film thickness measurement device 120 and the film thickness measurement device 130.

In the example shown in FIG. 12, both the film thickness measurement device 120 and the film thickness measurement device 130 are provided as measurement devices. However, at least one of the film thickness measurement device 120 and the film thickness measurement device 130 should be provided.

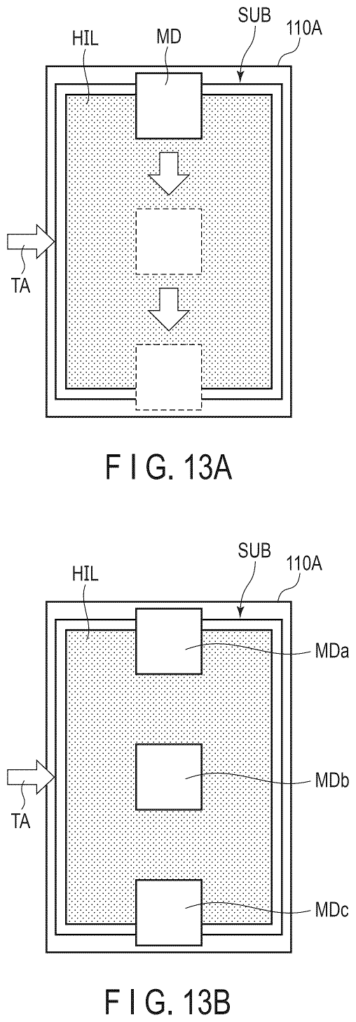

FIG. 13A is a diagram for explaining a method for measuring the thickness of a deposited layer at a plurality of positions. In the example shown here, the deposited layer is a hole injection layer HIL.

Here, the film thickness measurement device 120 and the film thickness measurement device 130 are collectively called a measurement device MD. The measurement device MD is configured to move in a direction intersecting with the conveyance direction TA of the processing substrate SUB and measures the thickness of the deposited layer at a plurality of positions while moving. In the example shown in the figure, the measurement device MD measures the thickness of the deposited layer at a plurality of positions, for example, three or more positions, relative to the processing substrate SUB carried in the chamber 110A. By measuring the thickness of the deposited layer at a plurality of positions, the variation in the thickness of the deposited layer in the plane of the processing substrate SUB can be calculated.

FIG. 13B is a diagram for explaining another method for measuring the thickness of a deposited layer at a plurality of positions. In the example shown here, the deposited layer is a hole injection layer HIL.

The example shown in FIG. 13B is different from that shown in FIG. 13A in respect that a plurality of measurement devices MDa, MDb, MDc, . . . are provided at intervals in a direction intersecting with the conveyance direction TA. In this example, the movement mechanism of the measurement device MD is not needed. The thickness of the deposited layer can be measured at a plurality of positions at short times.

Now, the process of measuring the thickness of a deposited layer is explained.

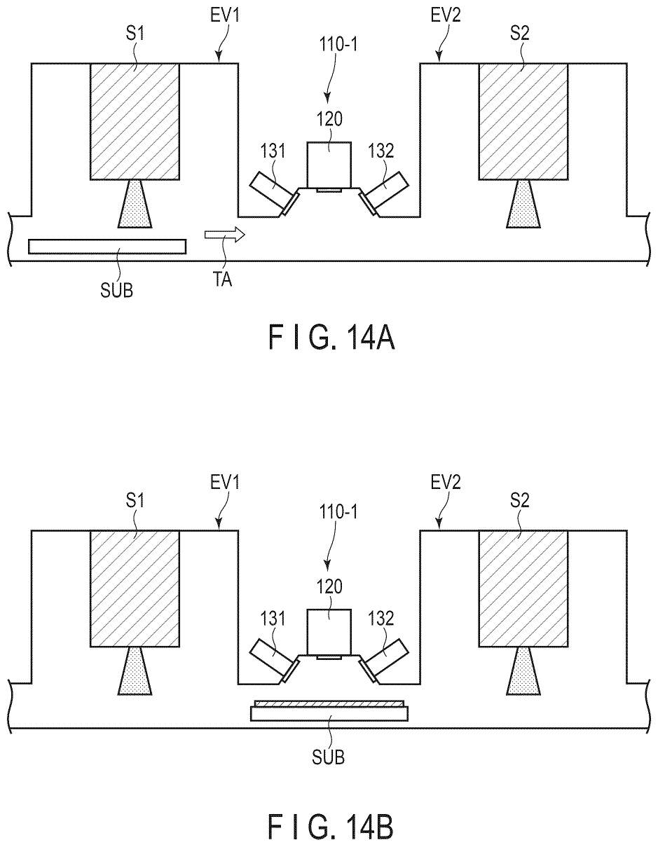

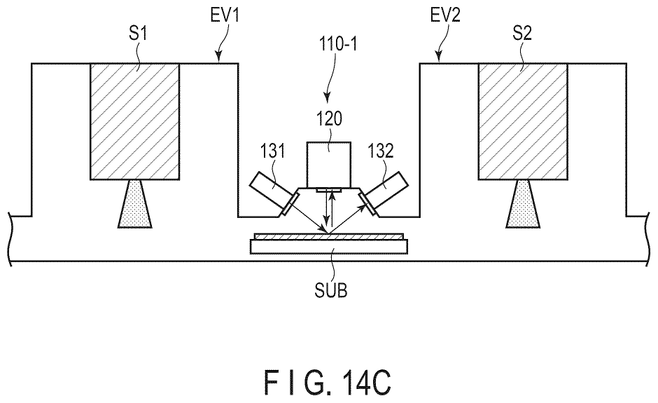

FIG. 14A shows a processing substrate SUB carried in the evaporation chamber EV1. The processing substrate SUB is conveyed in the conveyance direction TA. The material emitted from the evaporation source S1 is deposited on the processing substrate SUB which is conveyed.

FIG. 14B shows the processing substrate SUB carried in the measurement portion 110-1.

FIG. 14C shows the process of measuring the thickness of a deposited layer. The processing substrate SUB which reached the measurement portion 110-1 stops. In the state where the processing substrate SUB stops, the film thickness measurement device 120 and the film thickness measurement device 130 measure the thickness of the deposited layer. At this time, the thickness of the deposited layer is measured at a plurality of positions as shown in FIG. 13A or FIG. 13B.

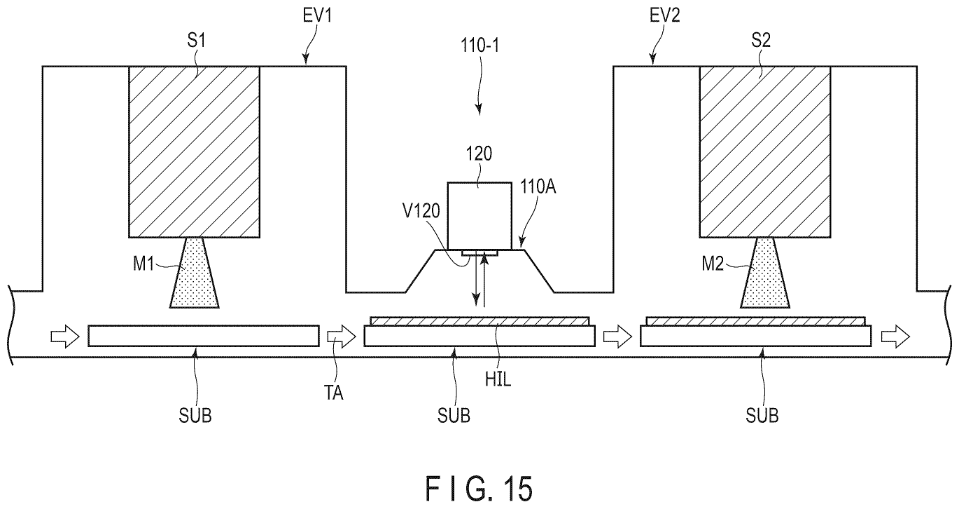

FIG. 15 is a diagram showing another configuration example of the measurement portion 110-1.

The configuration example shown in FIG. 15 is different from that shown in FIG. 12 in the following respects. Each measurement portion including the measurement portion 110-1 comprises the film thickness measurement device 120, and the film thickness measurement device 130 is omitted.

The film thickness measurement device 120 is suitable for the measurement of the total thickness of multilayer films as described above. Thus, the thickness of the deposited film formed in each evaporation chamber is calculated by, for example, the method explained below.

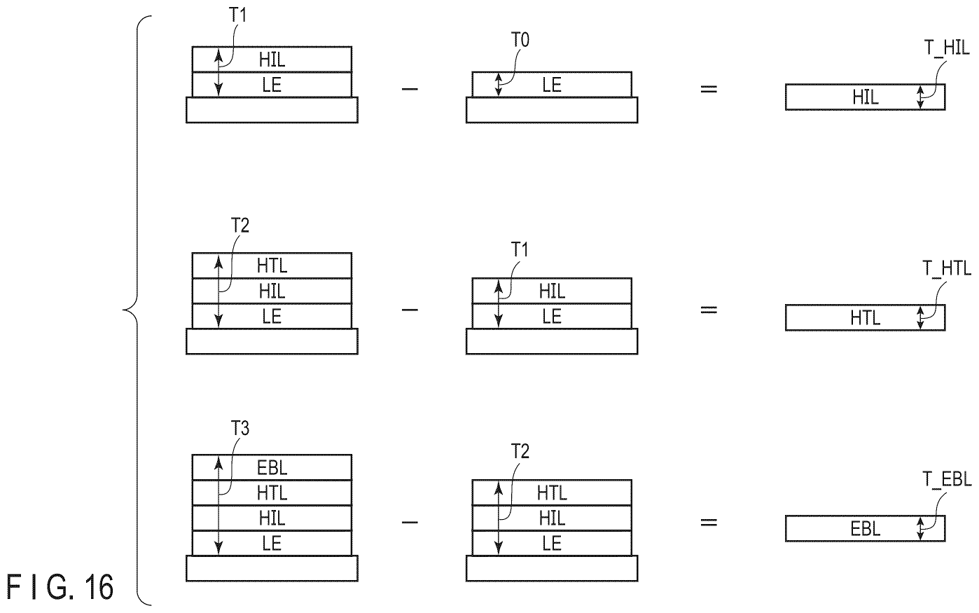

FIG. 16 is a diagram for explaining the method of calculating the thickness of each layer of a deposited layer by the film thickness measurement device 120 shown in FIG. 15.

For example, the film thickness measurement device 120 of the measurement portion 110-1 holds thickness T0 of the lower electrode LE in a storage portion in advance regarding the processing substrate SUB carried in the evaporation chamber EV1.

As shown in the upper part of FIG. 16, thickness T1 measured in the film thickness measurement device 120 of the measurement portion 110-1 immediately after the hole injection layer HIL is formed as the deposited layer is the total thickness of the lower electrode LE and the hole injection layer HIL. Subsequently, the film thickness measurement device 120 calculates thickness T_HIL of the hole injection layer HIL as the difference between thickness T1 and thickness T0.

The film thickness measurement device 120 of the measurement portion 110-2 holds total thickness T1 of the lower electrode LE and the hole injection layer HIL in a storage portion in advance regarding the processing substrate SUB carried in the evaporation chamber EV2.

As shown in the middle part of FIG. 16, thickness T2 measured in the film thickness measurement device 120 of the measurement portion 110-2 immediately after the hole transport layer HTL is formed as the deposited layer is the total thickness of the lower electrode LE, the hole injection layer HIL and the hole transport layer HTL. Subsequently, the film thickness measurement device 120 calculates thickness T_HTL of the hole transport layer HTL as the difference between thickness T2 and thickness T1.

The film thickness measurement device 120 of the measurement portion 110-3 holds total thickness T2 of the lower electrode LE, the hole injection layer HIL and the hole transport layer HTL in a storage portion in advance regarding the processing substrate SUB carried in the evaporation chamber EV3.

As shown in the lower part of FIG. 16, thickness T3 measured in the film thickness measurement device 120 of the measurement portion 110-3 immediately after the electron blocking layer EBL is formed as the deposited layer is the total thickness of the lower electrode LE, the hole injection layer HIL, the hole transport layer HTL and the electron blocking layer EBL. Subsequently, the film thickness measurement device 120 calculates thickness T_EBL of the electron blocking layer EBL as the difference between thickness T3 and thickness T2.

Thus, in this configuration example, each measurement portion comprises the film thickness measurement device 120, and the film thickness measurement device 130 is omitted. Even in this configuration example, in a manner similar to that of the configuration example described above, the thickness of the deposited layer formed in each evaporation chamber can be measured.

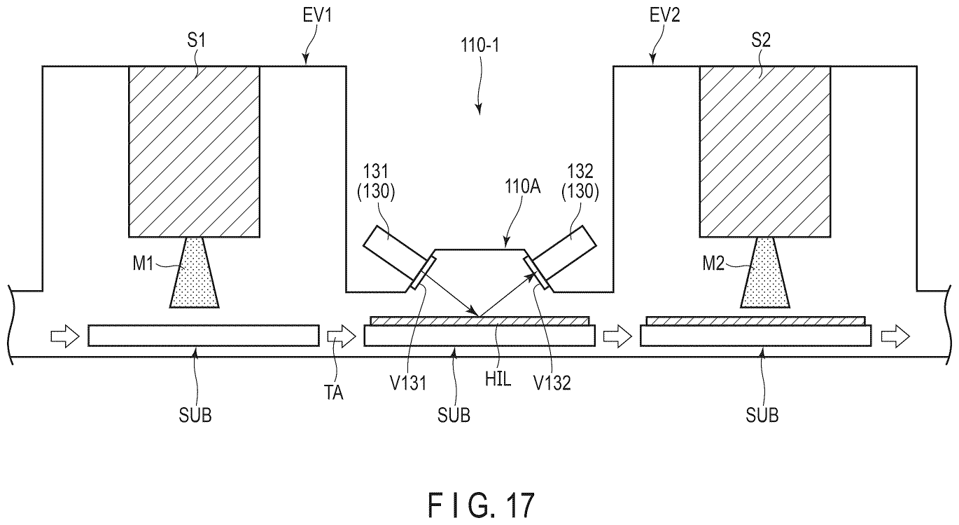

FIG. 17 is a diagram showing another configuration example of the measurement portion 110-1.

The configuration example shown in FIG. 17 is different from that shown in FIG. 12 in the following respects. Each measurement portion including the measurement portion 110-1 comprises the film thickness measurement device 130, and the film thickness measurement device 120 is omitted.

The film thickness measurement device 130 is suitable for the measurement of the total thickness of single-layer films as described above. Thus, in addition to an effect similar to that of the configuration examples described above, the configuration of the measurement device can be simplified, and the cost of the manufacturing device can be reduced.

As explained above, the embodiment can provide a manufacturing device of a display device and a manufacturing method of a display device such that the thicknesses of layers which are successively formed can be measured.

All of the manufacturing devices and manufacturing methods that can be implemented by a person of ordinary skill in the art through arbitrary design changes to the manufacturing device and manufacturing method described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A manufacturing device of a display device, comprising:
an evaporation chamber comprising an evaporation source configured to emit a material toward a conveyance path for conveying a processing substrate for the display device; and
a measurement portion provided on a downstream side of a conveyance direction of the processing substrate relative to the evaporation chamber, wherein
the measurement portion comprises:
a chamber comprising a transmissive window and connected to the evaporation chamber; and
a film thickness measurement device provided outside the chamber, facing the transmissive window and configured to optically measure a thickness of a deposited layer formed of the material deposited on the processing substrate.

2. The manufacturing device of claim 1, wherein
the film thickness measurement device comprises at least one of a spectroscopic interferometer and an ellipsometer.

3. The manufacturing device of claim 1, wherein
the film thickness measurement device is configured to measure the thickness of the deposited layer at a plurality of positions along a direction intersecting with the conveyance direction of the processing substrate.

4. The manufacturing device of claim 1, wherein
a plurality of sets each including the evaporation chamber and the measurement portion are provided,
the evaporation chambers and the measurement portions are alternately arranged along the conveyance path, and
the evaporation sources are configured to emit materials different from each other in the respective evaporation chambers.

5. A manufacturing method of a display device, comprising:
preparing a processing substrate in which a lower electrode is formed above a substrate, an inorganic insulating layer comprising an aperture overlapping the lower electrode is formed, and a partition comprising a lower portion located on the inorganic insulating layer and an upper portion located on the lower portion and protruding from a side surface of the lower portion is formed; and
forming an organic layer on the lower electrode in the aperture, wherein
the forming the organic layer includes:
carrying the processing substrate into an evaporation chamber;
depositing a material emitted from an evaporation source on the processing substrate while conveying the processing substrate in the evaporation chamber;
carrying the processing substrate carried out of the evaporation chamber into a chamber of a measurement portion; and
stopping the processing substrate and optically measuring a thickness of a deposited layer formed of the material deposited on the processing substrate in the measurement portion.

6. The manufacturing method of claim 5, wherein
the measuring is performed using at least one of a stereoscopic interferometer and an ellipsometer.

7. The manufacturing method of claim 5, wherein
the thickness of the deposited layer is measured at a plurality of positions along a direction intersecting with a conveyance direction of the processing substrate in the measuring process.

8. The manufacturing method of claim 5, further comprising
forming an upper electrode on the organic layer after the organic layer is formed, and
forming a cap layer on the upper electrode, wherein
the process of forming the organic layer, the upper electrode and the cap layer is a deposition process using the partition as a mask, and
the organic layer, the upper electrode and the cap layer formed immediately above the upper portion of the partition are spaced apart from the organic layer, the upper electrode and the cap layer formed immediately above the lower electrode in the aperture.

9. The manufacturing method of claim 8, further comprising
forming a sealing layer by an inorganic insulating material after forming the cap layer, wherein
the sealing layer covers the cap layer located on the partition, covers the cap layer located immediately above the lower electrode and is in contact with the partition.

10. The manufacturing method of claim 9, further comprising:
forming a patterned resist on the sealing layer after forming the sealing layer; and
removing the sealing layer, the cap layer, the upper electrode and the organic layer exposed from the resist in series by etching.
